(19) United States
(12) Patent Application Publication
(10) Pub. No.: US 2024/0178028 A1
(43) Pub. Date: May 30, 2024

(54) CARRIAGE SYSTEM CONTROL METHOD AND CARRIAGE SYSTEM CONTROL APPARATUS

(71) Applicant: SEMES CO., LTD., Cheonan-si (KR)

(72) Inventors: Kisub YOON, Cheonan-si (KR); Seokhee KIM, Cheonan-si (KR)

(73) Assignee: SEMES CO., LTD., Cheonan-si (KR)

(21) Appl. No.: 18/516,895

(22) Filed: Nov. 21, 2023

(30) Foreign Application Priority Data
Nov. 30, 2022 (KR) 10-2022-0164393

(51) Int. Cl. H01L 21/677; G08G 1/095; H01L 21/67

(52) U.S. Cl. CPC H01L 21/6773; G08G 1/095; H01L 21/67253; H01L 21/67294; H01L 21/67793

(57) ABSTRACT

Provided is a carriage system control method and carriage system control apparatus capable of preventing a transportation delay, the carriage system control method including (a) performing upper-level communication to receive bidirectional information by using wireless communication in a normal state from a track controller or a carriage moving along rails of a track and supplied with power through the track or power supply cables, (b) determining whether an abnormal state in which the upper-level communication is disabled has occurred, (c) determining whether current is being applied to the track or the power supply cables, when it is determined that the abnormal state has occurred, and (d) maintaining operation of the carriage or the track controller without closing a corresponding lane to prevent a transportation delay, when it is determined that current is being applied to the track or the power supply cables.

### CROSS-REFERENCE TO RELATED PATENT APPLICATION

This application claims the benefit of Korean Patent Application No. 10-2022-0164393, filed on Nov. 30, 2022, in the Korean Intellectual Property Office, the disclosure of which is incorporated herein in its entirety by reference.

### BACKGROUND OF THE INVENTION

### 1. Field of the Invention

The present invention relates to a carriage system control method and a carriage system control apparatus and, more particularly, to a carriage system control method and carriage system control apparatus capable of preventing a transportation delay.

### 2. Description of the Related Art

Semiconductor products are manufactured through hundreds of processes, and transportation occurs hundreds of thousands of times during the semiconductor manufacturing processes. To prevent the contamination, damage, and delivery mistakes of semiconductor materials during the transportation, semiconductor manufacturing lines use an overhead hoist transport (OHT) system as a transportation automation system.

The OHT system is a system for automating transportation between a numerous number of semiconductor processes, and serves to transport wafers stored in front opening unified pods (FOUPs) to manufacturing equipments of different production processes along tracks mounted on the ceiling.

The OHT system may include carriages moving along rails and supplied with power in a wireless manner by using power supply cables provided along the rails, and be operated and managed by an upper-level server for performing upper-level communication by receiving feedback information such as power status information or operation status information in a wireless manner from each carriage.

In general, when an upper-level communication module mounted in the carriage has an error or operates abnormally, although the carriage may normally move, the upper-level server determines that a serious accident has occurred on a corresponding lane, and takes follow-up measures for emergency by closing the entirety of the corresponding lane and providing a notification to an operator.

However, these follow-up measures for emergency cause a transportation delay everywhere including the corresponding lane until the closed lane is restored, and thus many problems such as a significant decrease in efficiency of transportation and productivity occur.

### SUMMARY OF THE INVENTION

The present invention provides a carriage system control method and carriage system control apparatus capable of constantly maintaining operation of a carriage or a track controller without closing a corresponding lane to prevent a transportation delay by determining an error of an upper-level communication module when upper-level communication is disabled and power is normally supplied to power supply cables. However, the above description is an example, and the scope of the present invention is not limited thereto.

According to an aspect of the present invention, there is provided a carriage system control method performed by an upper-level server, the carriage system control method including (a) performing upper-level communication to receive bidirectional information by using wireless communication in a normal state from a track controller or a carriage moving along rails of a track and supplied with power through the track or power supply cables, (b) determining whether an abnormal state in which the upper-level communication is disabled has occurred, (c) determining whether current is being applied to the track or the power supply cables, when it is determined that the abnormal state has occurred, and (d) maintaining operation of the carriage or the track controller without closing a corresponding lane to prevent a transportation delay, when it is determined that current is being applied to the track or the power supply cables.

In step (a), the carriage may be supplied with power in a wireless power transmission manner through the power supply cables by using a resonance frequency value.

In step (a), the bidirectional information may include feedback information indicating a current status of the carriage or the track controller.

In step (b), the upper-level server may determine the normal or abnormal state by using whether the bidirectional information is present.

In step (c), the upper-level server may determine whether power is being applied, by using the bidirectional information of a power supply unit or another adjacent carriage, which applies current to the track or the power supply cables.

The carriage system control method may further include (e) outputting a notification signal or a follow-up command signal while maintaining operation of the carriage or the track controller.

In step (e), the upper-level server may determine an error of communication and transmits a return command or a communication check command to the carriage when current is being applied to the track or the power supply cables and the carriage is moving.

In step (e), the upper-level server may determine an error of motion and transmits a tow command to an operator or a tow vehicle when current is being applied to the track or the power supply cables and the carriage is disabled to move.

The carriage may be an overhead hoist transport (OHT) for transporting semiconductor substrates or display boards, and the track controller may be a traffic light mounted at a curved section, a split section, or a combined section of rails.

The carriage system control method may further include (f) closing the corresponding lane to prevent a transportation accident, when it is determined that current to the track or the power supply cables is cut off.

According to another aspect of the present invention, there is provided a carriage system control apparatus including an upper-level communicator for performing upper-level communication to receive bidirectional information by using wireless communication in a normal state from a track controller or a carriage moving along rails of a track and supplied with power through the track or power supply cables, a communication disablement determiner for determining whether an abnormal state in which the upper-level communication is disabled has occurred, a current application determiner for determining whether current is being applied to the track or the power supply cables, when it is determined that the abnormal state has occurred, and a lane maintainer for maintaining operation of the carriage or the track controller without closing a corresponding lane to prevent a transportation delay, when it is determined that current is being applied to the track or the power supply cables.

The carriage may be supplied with power in a wireless power transmission manner through the power supply cables by using a resonance frequency value.

The bidirectional information may include feedback information indicating a current status of the carriage or the track controller.

The communication disablement determiner may determine the normal or abnormal state by using whether the bidirectional information is present.

The current application determiner may determine whether power is being applied, by using the bidirectional information of a power supply unit or another adjacent carriage, which applies current to the track or the power supply cables.

The carriage system control apparatus may further include a notification signal outputter for outputting a notification signal or a follow-up command signal while maintaining operation of the carriage or the track controller.

The notification signal outputter may determine an error of communication and transmit a return command or a communication check command to the carriage when current is being applied to the track or the power supply cables and the carriage is moving.

The notification signal outputter may determine an error of motion and transmit a tow command to an operator or a tow vehicle when current is being applied to the track or the power supply cables and the carriage is disabled to move.

The carriage system control apparatus may further include a lane closer for closing the corresponding lane to prevent a transportation accident, when it is determined that current to the track or the power supply cables is cut off.

According to another aspect of the present invention, there is provided a carriage system control apparatus including an upper-level communicator for performing upper-level communication to receive bidirectional information by using wireless communication in a normal state from a track controller or a carriage moving along rails of a track and supplied with power through the track or power supply cables, a communication disablement determiner for determining whether an abnormal state in which the upper-level communication is disabled has occurred, a current application determiner for determining whether current is being applied to the track or the power supply cables, when it is determined that the abnormal state has occurred, a lane maintainer for maintaining operation of the carriage or the track controller without closing a corresponding lane to prevent a transportation delay, when it is determined that current is being applied to the track or the power supply cables, a notification signal outputter for outputting a notification signal or a follow-up command signal while maintaining operation of the carriage or the track controller, and a lane closer for closing the corresponding lane to prevent a transportation accident, when it is determined that current to the track or the power supply cables is cut off, wherein the carriage is supplied with power in a wireless power transmission manner through the power supply cables by using a resonance frequency value, wherein the bidirectional information includes feedback information indicating a current status of the carriage or the track controller, wherein the communication disablement determiner determines the normal or abnormal state by using whether the bidirectional information is present, wherein the current application determiner determines whether power is being applied, by using the bidirectional information of a power supply unit or another adjacent carriage, which applies current to the track or the power supply cables, and wherein the notification signal outputter determines an error of communication and transmits a return command or a communication check command to the carriage when current is being applied to the track or the power supply cables and the carriage is moving, or determines an error of motion and transmits a tow command to an operator or a tow vehicle when current is being applied to the track or the power supply cables and the carriage is disabled to move.

### BRIEF DESCRIPTION OF THE DRAWINGS

The above and other features and advantages of the present invention will become more apparent by describing in detail embodiments thereof with reference to the attached drawings in which:

FIG. 1 is a conceptual view of a carriage system according to some embodiments of the present invention;

FIG. 2 is a perspective view of the carriage system of FIG. 1;

FIG. 3 is a schematic view of rails of the carriage system of FIG. 1;

FIG. 4 is a front view of a carriage of FIG. 3;

FIG. 5 is a side view of the carriage of FIG. 3;

FIG. 6 is a block diagram of the carriage of FIG. 3;

FIG. 7 is a block diagram of a carriage system control apparatus according to some embodiments of the present invention;

FIG. 8 is a flowchart of a carriage system control method according to some embodiments of the present invention; and

FIG. 9 is a flowchart of a carriage system control method according to other embodiments of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

The terminology used herein is for the purpose of describing particular embodiments and is not intended to limit the invention. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, components, and/or groups thereof, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

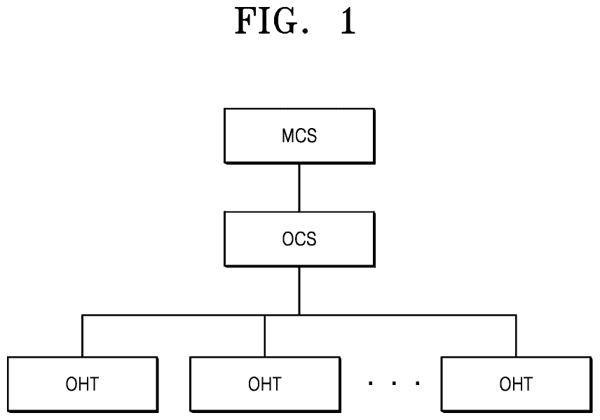

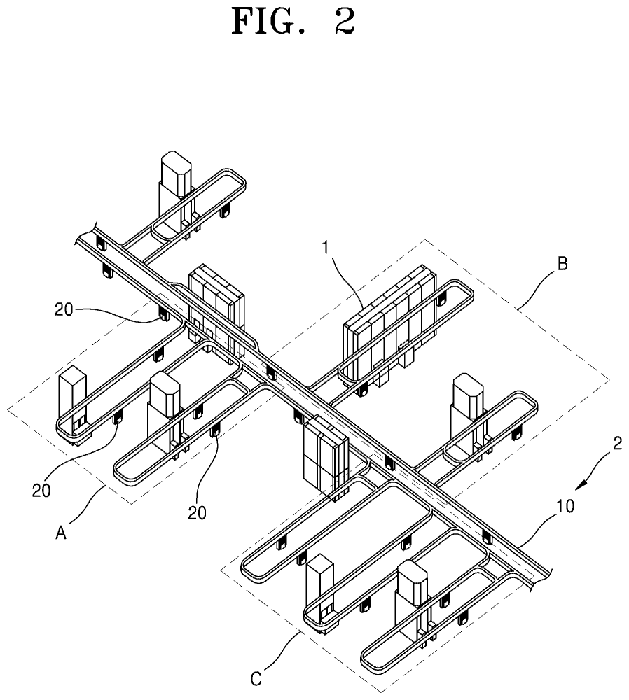

FIG. 1 is a conceptual view of a carriage system according to some embodiments of the present invention, and FIG. 2 is a perspective view of the carriage system of FIG. 1.

Overhead hoist transports (OHTs) 20 move along rails 10 mounted on the ceiling and are interfaced with an OHT control system (OCS) for giving transportation commands in a wireless communication manner. The OCS may receive a command related to transportation based on a work process from a material control system (MCS), searches for the shortest path from a departure to a destination, selects an OHT 20 at an optimal position for performing the transportation work, and gives a transportation command to the selected OHT 20 in order to complete the transportation work within the shortest time according to the command of the MCS. The OHT 20 transports materials from an arbitrary port to a destination port designated by the OCS based on the transportation command of the OCS.

When OHT vehicles transport articles according to transportation commands, in order to ensure the reliability and safety of transportation, for example, in order to prevent collision between the OHT vehicles or delivery mistakes, an OHT controller specifically and precisely control the OHT vehicles based on speed information, position information, or the like obtained by sensing operations of the OHT vehicles.

Various errors may occur during the operations of the OHT vehicles and these errors may cause a serious accident in transportation of the OHT vehicles. Therefore, when an error has occurred during operation of an OHT vehicle, the OHT controller stops the OHT vehicle itself by operating a brake of the OHT vehicle.

The stopping of a specific OHT vehicle due to an error while tens to hundreds of OHT vehicles are simultaneously operating on rails of an OHT system leads to successive slowdown or stopping of other adjacent OHT vehicles, thereby causing a decrease in efficiency and performance of the whole OHT system.

Various methods have been proposed to solve problems of an OHT vehicle having an error of motion. For example, in order to restart or tow an OHT vehicle which is braked to stop, an operator manually resets the OHT vehicle by supplying additional power to the OHT vehicle and releasing the brake.

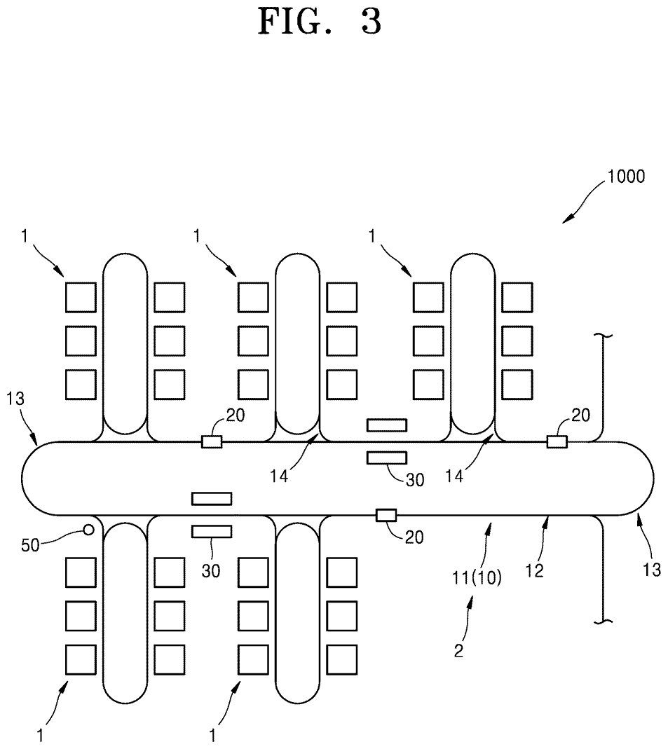

FIG. 3 is a schematic view of the rails 10 of the carriage system of FIG. 1.

As shown in FIGS. 1 to 3, reference numeral 1 denotes a plurality of semiconductor manufacturing equipments installed in a semiconductor manufacturing plant, and reference numeral 10 denotes rails for providing transportation paths 11 for transporting articles such as front opening unified pods (FOUPs) between the semiconductor manufacturing equipments 1. Reference numeral 20 denotes a plurality of carriages for transporting the articles while moving along the transportation paths 11, and reference numeral 30 denotes one or more buffers for providing temporary storage spaces for the articles. The rails 10 are disposed on the ceiling of the semiconductor manufacturing plant. Each carriage 20 may transport an article from a specific semiconductor manufacturing equipment 1 to another semiconductor manufacturing equipment 1 directly or after temporarily storing the article in the buffer 30. The buffers 30 may be side rail buffers mounted at sides of the transportation paths 11, or under rail buffers mounted under the transportation paths 11.

Article transportation equipment according to an embodiment of the present invention includes an OHT system, and the OHT system includes the rails 10 and the plurality of carriages 20. The above-described article transportation equipment according to an embodiment of the present invention may be configured in such a manner that the carriages 20 operate by receiving driving power from a power supply device through a power supply unit and a power receiving unit, and further include an integrated control device to automatically operate the carriages 20. Although not shown in the drawings, the article transportation equipment may further include equipments such as a maintenance lifter for maintaining or repairing the carriages 20, a vehicle lifter, and a test bench.

Referring to FIG. 3, the transportation paths 11 may include one or more linear sections 12 having a linear line shape, one or more curved sections 13 having a curved line shape, and one or more joint sections 14 for splitting and/or combining paths.

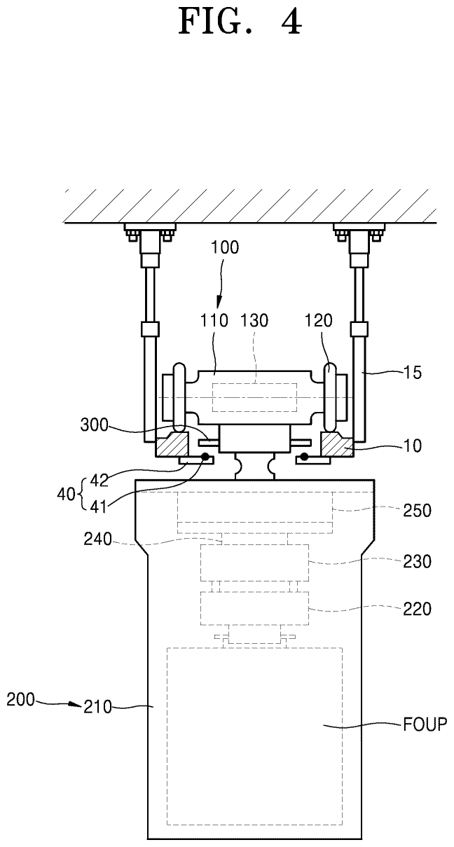

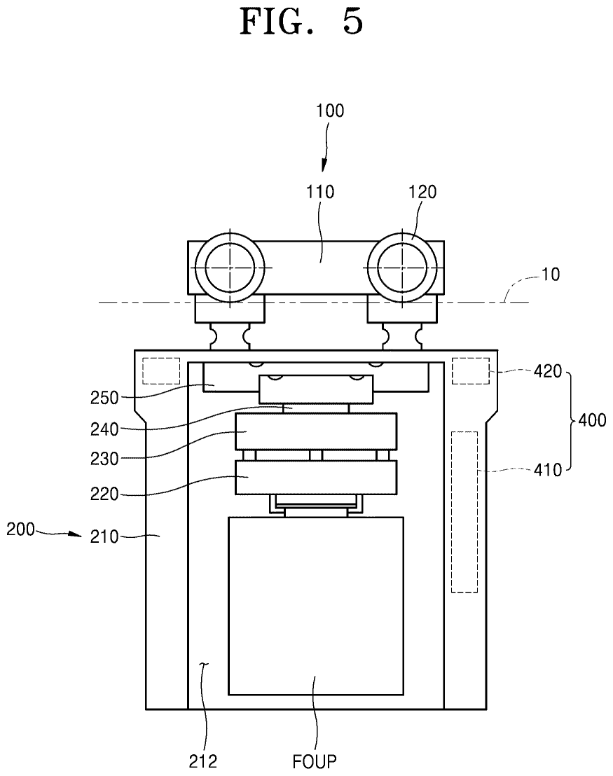

FIG. 4 is a front view of the carriage 20 of FIG. 3, and FIG. 5 is a side view of the carriage 20 of FIG. 3.

Referring to FIGS. 4 and 5, the rails 10 include a pair of rail members spaced apart from each other in a lateral direction and are mounted on the ceiling of a semiconductor manufacturing plant by rail supports 15. The rail supports 15 may have lower ends supporting the pair of rail members, and upper ends fixed to the ceiling of the semiconductor manufacturing plant. The pair of rail members may be configured to provide running surfaces thereon.

As shown in FIG. 4, a power supply unit 40 includes power supply cables 41 mounted under the rails 10 along the transportation paths 11. A pair of power supply cables 41 are provided. The power supply cables 41 may be supported by line supports 42 disposed between the pair of rail members and attached to the rails 10. The power supply cables 41 are electrically connected to a power supply device for providing driving power. For example, the power supply cables 41 may be mounted only on the linear sections 12 of the transportation paths 11 and not mounted on the curved sections 13 and the joint sections 14 of the transportation paths 11. As such, the transportation paths 11 may have power supply sections where the power supply cables 41 are mounted and no power supply sections where the power supply cables 41 are not mounted.

Each carriage 20 includes a vehicle 100 moving along the rails 10, and a hoist 200 supporting an article such as a FOUP from under the vehicle 100. The hoist 200 moves together with the vehicle 100 and supports the article.

The vehicle 100 includes a chassis 110 and wheels 120. Axles extending in a lateral direction are attached to the chassis 110. A plurality of axles are provided and may be spaced from each other in a longitudinal direction. The wheels 120 are running wheels which provide mobility to the chassis 110 to move as guided by the rails 10. The wheels 120 may be attached to both ends of the axles to roll in contact with the running surfaces of the pair of rail members. The vehicle 100 further includes a wheel driving unit 130 for providing power to rotate the wheels 120. For example, the wheel driving unit 130 may be configured to rotate the axles.

The hoist 200 includes a hoist housing 210. The hoist housing 210 is connected to the vehicle 100 from under the rails 10. The top of the hoist housing 210 may be connected to the bottom of the chassis 110 by one or more connectors. The hoist housing 210 may provide a storage space 212 where the article is stored.

The hoist housing 210 is configured to have a structure, left, right, and bottom sides of which are open to move the article leftward, rightward, and downward from the storage space 212.

In addition, the hoist 200 further includes a hand unit 220 for gripping or ungripping the article, and a hand moving unit for moving the hand unit 220 between a first position and a second position. The first position is a position at which the article gripped by the hand unit 220 is stored in the storage space 212 of the hoist housing 210, and the second position is a position outside the hoist housing 210 away from the first position. The hoist 200 includes a vertical driving unit 230, a rotary driving unit 240, and a horizontal driving unit 250 as the hand moving unit.

The hand unit 220 may include a hand for gripping or ungripping the article, and a hand support supporting the hand. The vertical driving unit 230 moves the hand unit 220 in a vertical direction. The vertical driving unit 230 may move the hand unit 220 in a vertical direction by winding or unwinding one or more belts around a drum. The rotary driving unit 240 rotates the hand unit 220 about a vertical axis, and the horizontal driving unit 250 moves the hand unit 220 in a horizontal direction. For example, the hand unit 220 may be moved in a vertical direction by the vertical driving unit 230, the vertical driving unit 230 may be rotated about a vertical axis by the rotary driving unit 240, or the rotary driving unit 240 may be moved in a horizontal direction by the horizontal driving unit 250, such that the article gripped by the hand unit 220 may be moved in a vertical direction, rotated about a vertical axis, or moved in a horizontal direction.

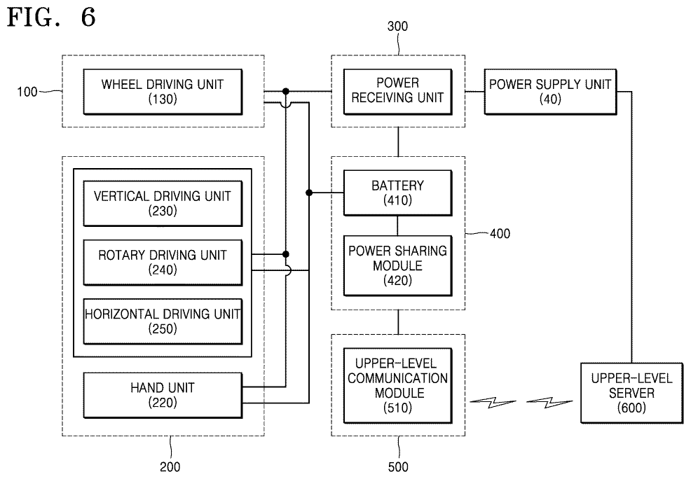

FIG. 6 is a block diagram of the carriage 20 of FIG. 3.

As shown in FIGS. 1 to 6, each carriage 20 includes a vehicle body, and the vehicle body includes the above-described vehicle 100 and hoist 200. As shown in FIGS. 4 and 5, each carriage 20 further includes a first power source device or main power source device 300 for receiving power from the power supply cables 41 in a non-contact manner and supplying the power to the vehicle body, and a second power source device or sub power source device 400 for supplying power stored in a battery 410 to the vehicle body and sharing the power with an adjacent vehicle body by using a power sharing module 420.

The first power source device 300 includes a power receiving unit provided below the vehicle 100 or above the hoist 200 to face the power supply cables 41. The power receiving unit may include a pickup coil and a rectifier. Because alternating current (AC) flows through the power supply cables 41, the direction and intensity of magnetic flux generated near the power supply cables 41 always fluctuate. The pickup coil may generate an induced voltage by inducing electrons based on the fluctuation of the magnetic flux. The generated induced voltage is an AC voltage but may be converted into a direct current (DC) voltage by a rectifier before being supplied to the vehicle body.

The battery 410 may receive power from the first power source device 300, store the received power, and supply the stored power to the vehicle body.

The power sharing module 420 may be electrically connected to the battery 410 to receive or supply battery power from or to the battery 410 of another vehicle body. That is, the power sharing module 420 may share battery power with another vehicle body.

The battery 410 and the power sharing module 420 are provided at a plurality of positions of the vehicle body. As shown in FIG. 5, the battery 410 and the power sharing module 420 may be mounted in the hoist 200 which is structurally more advantageous in ensuring a mounting space. Specifically, the battery 410 and the power sharing module 420 may be embedded in the hoist housing 210. In this case, a plurality of power sharing modules 420 may be provided to easily share power with another adjacent vehicle body.

A communication device 500 may be mounted in the vehicle 100 or the hoist 200 to enable wireless communication with various communication devices.

The communication device 500 may include an upper-level communication module 510 capable of transmitting feedback information such as current power status information or operation status information to an upper-level server 600.

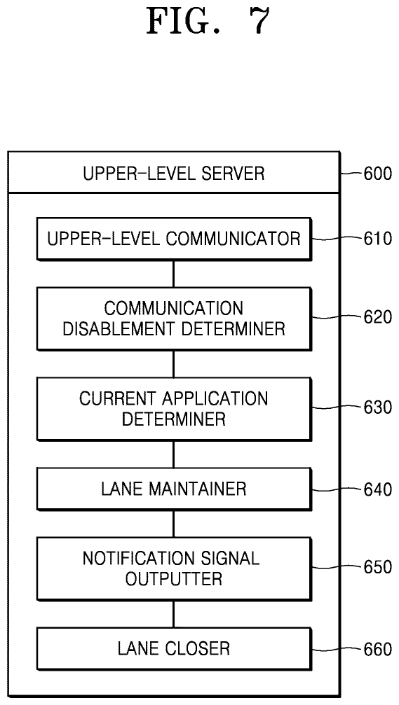

FIG. 7 is a block diagram of a carriage system control apparatus according to some embodiments of the present invention.

As shown in FIG. 7, the carriage system control apparatus according to some embodiments of the present invention, i.e., the upper-level server 600, may include an upper-level communicator 610 for performing upper-level communication to receive bidirectional information by using wireless communication in a normal state from a track controller 50 or the carriage 20 moving along the rails 10 of a track 2 and supplied with power through the track 2 or the power supply cables 41, a communication disablement determiner 620 for determining whether an abnormal state in which the upper-level communication is disabled has occurred, a current application determiner 630 for determining whether current is being applied to the track 2 or the power supply cables 41, when it is determined that the abnormal state has occurred, a lane maintainer 640 for maintaining operation of the carriage 20 or the track controller 50 without closing a corresponding lane to prevent a transportation delay, when it is determined that current is being applied to the track 2 or the power supply cables 41, a notification signal outputter 650 for outputting a notification signal or a follow-up command signal while maintaining operation of the carriage 20 or the track controller 50, and a lane closer 660 for closing the corresponding lane to prevent a transportation accident, when it is determined that current to the track 2 or the power supply cables 41 is cut off.

The carriage 20 may be supplied with power in a wireless power transmission manner through the power supply cables 41 by using a resonance frequency value.

The bidirectional information may include feedback information indicating a current status of the carriage 20 or the track controller 50.

The communication disablement determiner 620 may determine the normal or abnormal state by using whether the bidirectional information is present.

The current application determiner 630 may determine whether power is being applied, by using the bidirectional information of the power supply unit 40 or another adjacent carriage 20, which applies current to the track 2 or the power supply cables 41.

The notification signal outputter 650 may determine an error of communication and transmit a return command or a communication check command to the carriage 20 when current is being applied to the track 2 or the power supply cables 41 and the carriage 20 is moving.

The notification signal outputter 650 may determine an error of motion and transmit a tow command to an operator or a tow vehicle when current is being applied to the track 2 or the power supply cables 41 and the carriage 20 is disabled to move.

Therefore, according to the present invention, a series of processes for determining whether current is being applied to the track 2 or the power supply cables 41, when it is determined that an abnormal state in which upper-level communication is disabled has occurred while the upper-level communication is being performed to receive bidirectional information by using wireless communication in a normal state from the carriage 20 or the track controller 50, outputting a notification signal or a follow-up command signal while maintaining operation of the carriage 20 or the track controller 50 without closing a corresponding lane to prevent a transportation delay, when it is determined that current is being applied to the track 2 or the power supply cables 41, and closing the corresponding lane to prevent a transportation accident, when it is determined that current to the track 2 or the power supply cables 41 is cut off may be performed.

Accordingly, operation of the carriage 20 or the track controller 50 may be constantly maintained without closing a corresponding lane to prevent a transportation delay by determining an error of the upper-level communication module 510 when upper-level communication is disabled and power is normally supplied to the power supply cables 41, and thus efficiency of transportation and productivity may be greatly increased.

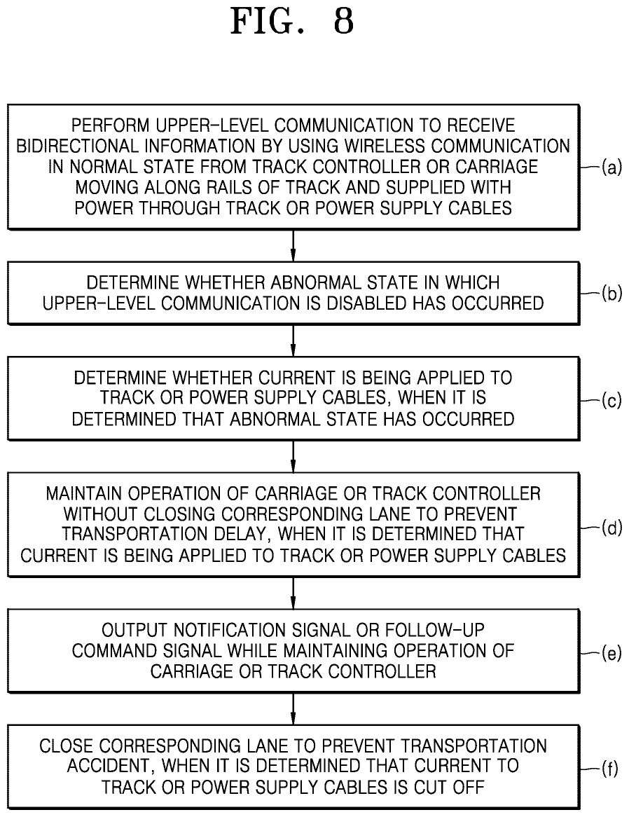

FIG. 8 is a flowchart of a carriage system control method according to some embodiments of the present invention.

As shown in FIG. 8, the carriage system control method according to some embodiments of the present invention may be performed by the upper-level server 600 and include (a) performing upper-level communication to receive bidirectional information by using wireless communication in a normal state from a track controller 50 or the carriage 20 moving along the rails 10 of the track 2 and supplied with power through the track 2 or the power supply cables 41, (b) determining whether an abnormal state in which the upper-level communication is disabled has occurred, (c) determining whether current is being applied to the track 2 or the power supply cables 41, when it is determined that the abnormal state has occurred, (d) maintaining operation of the carriage 20 or the track controller 50 without closing a corresponding lane to prevent a transportation delay, when it is determined that current is being applied to the track 2 or the power supply cables 41, (e) outputting a notification signal or a follow-up command signal while maintaining operation of the carriage 20 or the track controller 50, and (f) closing the corresponding lane to prevent a transportation accident, when it is determined that current to the track 2 or the power supply cables 41 is cut off.

In step (a), the carriage 20 may be supplied with power in a wireless power transmission manner through the power supply cables 41 by using a resonance frequency value.

In step (a), the bidirectional information may include feedback information indicating a current status of the carriage 20 or the track controller 50.

In step (b), the upper-level server 600 may determine the normal or abnormal state by using whether the bidirectional information is present.

In step (c), the upper-level server 600 may determine whether power is being applied, by using the bidirectional information of the power supply unit 40 or another adjacent carriage 20, which applies current to the track 2 or the power supply cables 41.

In step (e), the upper-level server 600 may determine an error of the upper-level communication module 510 and transmit a return command or a communication check command to the carriage 20 when current is being applied to the track 2 or the power supply cables 41 and the carriage 20 is moving.

In step (e), the upper-level server 600 may determine an error of motion and transmit a tow command to an operator or a tow vehicle when current is being applied to the track 2 or the power supply cables 41 and the carriage 20 is disabled to move.

The carriage 20 may be an OHT for transporting semiconductor substrates or display boards, and the track controller 50 may be a traffic light mounted at a curved section, a split section, or a combined section of rails.

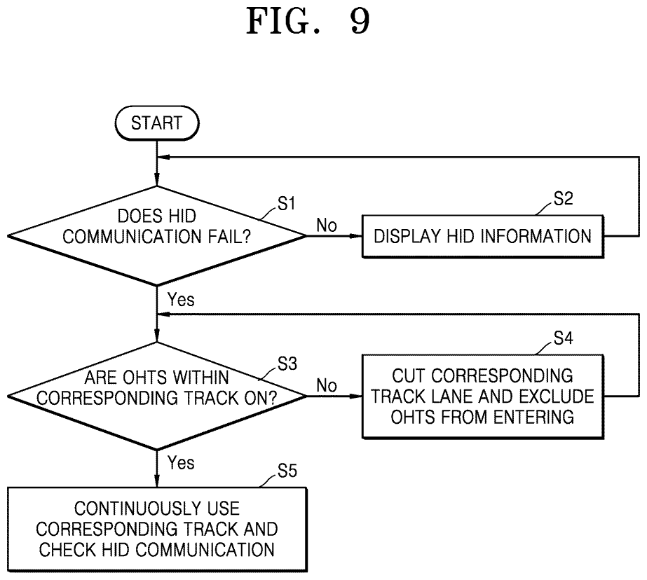

FIG. 9 is a flowchart of a carriage system control method according to other embodiments of the present invention.

As shown in FIG. 9, in the carriage system control method according to other embodiments of the present invention, when high-efficiency inductive power distribution (HID) communication succeeds (S1), HID information is displayed on a display device or the like (S2). When HID communication fails, it is determined whether wireless power supply to OHTs within a corresponding track is in an “ON” state (S3). When an OFF state is determined, a lane of the corresponding track may be closed and the OHTs may be excluded from entering (S4). When an ON state is determined, the lane of the corresponding track may be continuously used and HID communication may be checked (S5).

Therefore, when wireless power supply to OHTs within the corresponding track is in an “ON” state, the lane of the corresponding track may be continuously used to prevent a transportation delay and thus efficiency of transportation and productivity may be greatly increased.

According to the afore-described embodiments of the present invention, operation of a carriage or a track controller may be constantly maintained without closing a corresponding lane to prevent a transportation delay by determining an error of an upper-level communication module when upper-level communication is disabled and power is normally supplied to power supply cables, and thus efficiency of transportation and productivity may be greatly increased. However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A carriage system control method performed by an upper-level server, the carriage system control method comprising:
(a) performing upper-level communication to receive bidirectional information by using wireless communication in a normal state from a track controller or a carriage moving along rails of a track and supplied with power through the track or power supply cables;
(b) determining whether an abnormal state in which the upper-level communication is disabled has occurred;
(c) determining whether current is being applied to the track or the power supply cables, when it is determined that the abnormal state has occurred; and
(d) maintaining operation of the carriage or the track controller without closing a corresponding lane to prevent a transportation delay, when it is determined that current is being applied to the track or the power supply cables.

2. The carriage system control method of claim 1, wherein, in step (a), the carriage is supplied with power in a wireless power transmission manner through the power supply cables by using a resonance frequency value.

3. The carriage system control method of claim 1, wherein, in step (a), the bidirectional information comprises feedback information indicating a current status of the carriage or the track controller.

4. The carriage system control method of claim 1, wherein, in step (b), the upper-level server determines the normal or abnormal state by using whether the bidirectional information is present.

5. The carriage system control method of claim 1, wherein, in step (c), the upper-level server determines whether power is being applied, by using the bidirectional information of a power supply unit or another adjacent carriage, which applies current to the track or the power supply cables.

6. The carriage system control method of claim 1, further comprising (e) outputting a notification signal or a follow-up command signal while maintaining operation of the carriage or the track controller.

7. The carriage system control method of claim 6, wherein, in step (e), the upper-level server determines an error of communication and transmits a return command or a communication check command to the carriage when current is being applied to the track or the power supply cables and the carriage is moving.

8. The carriage system control method of claim 6, wherein, in step (e), the upper-level server determines an error of motion and transmits a tow command to an operator or a tow vehicle when current is being applied to the track or the power supply cables and the carriage is disabled to move.

9. The carriage system control method of claim 1, wherein the carriage is an overhead hoist transport (OHT) for transporting semiconductor substrates or display boards, and
wherein the track controller is a traffic light mounted at a curved section, a split section, or a combined section of rails.

10. The carriage system control method of claim 1, further comprising (f) closing the corresponding lane to prevent a transportation accident, when it is determined that current to the track or the power supply cables is cut off.

11. A carriage system control apparatus comprising:
an upper-level communicator for performing upper-level communication to receive bidirectional information by using wireless communication in a normal state from a track controller or a carriage moving along rails of a track and supplied with power through the track or power supply cables;
a communication disablement determiner for determining whether an abnormal state in which the upper-level communication is disabled has occurred;
a current application determiner for determining whether current is being applied to the track or the power supply cables, when it is determined that the abnormal state has occurred; and
a lane maintainer for maintaining operation of the carriage or the track controller without closing a corresponding lane to prevent a transportation delay, when it is determined that current is being applied to the track or the power supply cables.

12. The carriage system control apparatus of claim 11, wherein the carriage is supplied with power in a wireless power transmission manner through the power supply cables by using a resonance frequency value.

13. The carriage system control apparatus of claim 11, wherein the bidirectional information comprises feedback information indicating a current status of the carriage or the track controller.

14. The carriage system control apparatus of claim 11, wherein the communication disablement determiner determines the normal or abnormal state by using whether the bidirectional information is present.

15. The carriage system control apparatus of claim 11, wherein the current application determiner determines whether power is being applied, by using the bidirectional information of a power supply unit or another adjacent carriage, which applies current to the track or the power supply cables.

16. The carriage system control apparatus of claim 11, further comprising a notification signal outputter for outputting a notification signal or a follow-up command signal while maintaining operation of the carriage or the track controller.

17. The carriage system control apparatus of claim 16, wherein the notification signal outputter determines an error of communication and transmits a return command or a communication check command to the carriage when current is being applied to the track or the power supply cables and the carriage is moving.

18. The carriage system control apparatus of claim 16, wherein the notification signal outputter determines an error of motion and transmits a tow command to an operator or a tow vehicle when current is being applied to the track or the power supply cables and the carriage is disabled to move.

19. The carriage system control apparatus of claim 11, further comprising a lane closer for closing the corresponding lane to prevent a transportation accident, when it is determined that current to the track or the power supply cables is cut off.

20. A carriage system control apparatus comprising:
an upper-level communicator for performing upper-level communication to receive bidirectional information by using wireless communication in a normal state from a track controller or a carriage moving along rails of a track and supplied with power through the track or power supply cables;
a communication disablement determiner for determining whether an abnormal state in which the upper-level communication is disabled has occurred;
a current application determiner for determining whether current is being applied to the track or the power supply cables, when it is determined that the abnormal state has occurred;
a lane maintainer for maintaining operation of the carriage or the track controller without closing a corresponding lane to prevent a transportation delay, when it is determined that current is being applied to the track or the power supply cables;
a notification signal outputter for outputting a notification signal or a follow-up command signal while maintaining operation of the carriage or the track controller; and
a lane closer for closing the corresponding lane to prevent a transportation accident, when it is determined that current to the track or the power supply cables is cut off,
wherein the carriage is supplied with power in a wireless power transmission manner through the power supply cables by using a resonance frequency value,
wherein the bidirectional information comprises feedback information indicating a current status of the carriage or the track controller,
wherein the communication disablement determiner determines the normal or abnormal state by using whether the bidirectional information is present,
wherein the current application determiner determines whether power is being applied, by using the bidirectional information of a power supply unit or another adjacent carriage, which applies current to the track or the power supply cables, and
wherein the notification signal outputter determines an error of communication and transmits a return command or a communication check command to the carriage when current is being applied to the track or the power supply cables and the carriage is moving, or determines an error of motion and transmits a tow command to an operator or a tow vehicle when current is being applied to the track or the power supply cables and the carriage is disabled to move.
